(19) United States
(12) Patent Application Publication
(10) Pub. No.: US 2026/0018508 A1
(43) Pub. Date: Jan. 15, 2026

(54) BACKSIDE DEEP TRENCH CAPACITOR

(71) Applicant: International Business Machines Corporation, Armonk, NY (US)

(72) Inventors: Xiaoming Yang, Clifton Park, NY (US); Tao Li, Slingerlands, NY (US); Ruilong Xie, Niskayuna, NY (US); Robert Gauthier, Williston, VT (US)

(21) Appl. No.: 18/772,893

(22) Filed: Jul. 15, 2024

(51) Int. Cl. H01L 23/522; H01L 23/528; H01L 29/06; H01L 29/417; H01L 29/423; H01L 29/775; H01L 29/786; H01L 29/94

(52) U.S. Cl. CPC H01L 23/5223; H01L 23/5226; H01L 23/5283; H01L 23/5286; H10D 1/665; H10D 30/43; H10D 30/6729; H10D 30/6735; H10D 30/6757; H10D 62/121

(57) ABSTRACT

A semiconductor device is provided including a backside deep trench capacitor present in a deep trench device region and electrically connected to a source/drain region of a transistor and to a backside back-end-of-the-line (BEOL) structure. In some embodiments, the semiconductor device can also include a logic device region including at least one logic transistor that is located adjacent to the deep trench device region.

### BACKGROUND

The present application relates to semiconductor technology, and more particularly to a semiconductor device including a backside deep trench capacitor electrically connected to a source/drain region of a transistor and to a backside back-end-of-the-line (BEOL) structure that is configured to delivery power to the transistor.

Backside power delivery refers to a novel technique where power supply lines are routed on the backside of a semiconductor chip or integrated circuit (IC), rather than the traditional frontside. Backside power delivery offers several advantages, including increased logic density and improved power and performance (better signal integrity, reduced noise and improved overall chip performance).

### SUMMARY

A semiconductor device is provided including a backside deep trench capacitor present in a deep trench device region and electrically connected to a source/drain region of a transistor and to a backside BEOL structure. In some embodiments, the semiconductor device can also include a logic device region including at least one logic transistor that is located adjacent to the deep trench device region.

In one embodiment of the present application, the semiconductor device includes a deep trench device transistor including a gate structure and a pair of source/drain regions, a backside deep trench capacitor located beneath the deep trench device transistor, and a backside BEOL structure located beneath the backside deep trench capacitor. In this embodiment, the backside deep trench capacitor is electrically connected to a first source/drain region of the pair of source/drain regions by a combination of a backside via contact structure, a frontside power via structure and a frontside power via structure-to-source/drain contact structure, and the backside deep trench capacitor is further electrically connected to the backside BEOL structure by a last level backside power via.

In another embodiment of the present application, the semiconductor device includes a deep trench device transistor including a gate structure and a pair of source/drain regions, a backside deep trench capacitor located beneath the deep trench device transistor, and a backside BEOL structure located beneath the backside deep trench capacitor, in which the backside deep trench capacitor is electrically connected to a first source/drain region of the pair of source/drain regions by a combination of a first backside via contact structure, a first frontside power via structure and a frontside power via structure-to-source/drain contact structure, and the backside deep trench capacitor is further electrically connected to the backside BEOL structure by a last level backside power via. The semiconductor device of this embodiment further includes a second frontside power via structure located laterally adjacent to the first frontside power via structure, in which the second frontside power via structure is electrically connected to the backside BEOL structure by a second backside via contact structure and a backside power via stack.

### BRIEF DESCRIPTION OF THE DRAWINGS

FIG. 1 is a top down view of a device layout that can be employed in the present application, the device layout including a logic device region and a deep trench device region.

FIGS. 2A-2B are cross sectional views of an exemplary first structure in the logic device region and an exemplary second structure in the deep trench device region and through cut A-A and cut B-B, respectively, that can be employed in accordance with an embodiment of the present application.

FIG. 3 is a top down view of a device layout as shown in FIG. 1 and including a frontside power via structure.

FIGS. 4A-4B are cross sectional views of the exemplary first structure and the exemplary second structure of FIGS. 2A-2B, respectively, after forming a frontside power via structure in each of the deep trench device region and the logic device region.

FIG. 5 is a top down view of a device layout as shown in FIG. 3 and including frontside contact structures.

FIGS. 6A-6B are cross sectional views of the exemplary first structure and the exemplary second structure of FIGS. 4A-4B, respectively, after forming a middle-of-the-line (MOL) level including frontside contact structures, a frontside BEOL structure, and a carrier wafer.

FIGS. 7A-7B are cross sectional views of the exemplary first structure and the exemplary second structure of FIGS. 6A-6B, respectively, after wafer flipping, and removal of a semiconductor base substrate layer.

FIGS. 8A-8B are cross sectional views of the exemplary first structure and the exemplary second structure of FIGS. 7A-7B, respectively, after removing an etch stop layer.

FIGS. 9A-9B are cross sectional views of the exemplary first structure and the exemplary second structure of FIGS. 8A-8B, respectively, after forming backside contact via openings in a semiconductor device layer.

FIGS. 10A-10B are cross sectional views of the exemplary first structure and the exemplary second structure of FIGS. 9A-9B, respectively, after forming a backside via contact liner and a recessed dielectric layer in each backside contact via opening.

FIGS. 11A-11B are cross sectional views of the exemplary first structure and the exemplary second structure of FIGS. 10A-10B, respectively, after forming a backside contact via structure in each backside via opening.

FIGS. 12A-12B are cross sectional views of the exemplary first structure and the exemplary second structure of FIGS. 11A-11B, respectively, after forming backside power rails in the logic device region and forming a deep trench opening in the deep trench device region.

FIGS. 13A-13B are cross sectional views of the exemplary first structure and the exemplary second structure of FIGS. 12A-12B, respectively, after forming a backside deep trench capacitor in the deep trench opening, last level backside power vias and a backside BEOL structure.

FIGS. 14A-14B are cross sectional views of the exemplary first structure and the exemplary second structure through cut A-A and cut B-B, respectively, in accordance with an alternative embodiment of the present application.

FIGS. 15A-15B are cross sectional views of the exemplary first structure and the exemplary second structure through cut A-A and cut B-B, respectively, in accordance with another alternative embodiment of the present application.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain region. In the embodiment described in the present application, the transistor is a nanosheet transistor. A nanosheet transistor is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. The gate structure includes a gate dielectric and a gate electrode. The gate structure wraps around each of the spaced apart semiconductor channel material nanosheets. Nanosheet transistors provide considerable scaling with high drive current capability. Nanosheet transistors provide a larger drive current for a given footprint compared to finFET technology. Although nanosheet transistors are described in this application, this application is not limited to nanosheet transistors. Instead, the present application can be used for finFETs, nanowire FETs, planar FETs, fork sheet transistors, stacked FETs or any combination of such FETs including nanosheet transistors.

In the present application, the semiconductor device includes a frontside and a backside. The frontside includes a side of the device that includes at least one transistor, frontside contact structures, and a frontside BEOL structure. The backside of the semiconductor device is the side of the device that is opposite the frontside. The backside includes backside power rails, a backside deep trench capacitor and a backside BEOL structure. The backside BEOL structure can be a backside power distribution network that is capable of delivering power to the transistor through the backside of the semiconductor device. The backside deep trench capacitor is a device that stores electrical energy by accumulating electric charges on two closely spaces capacitor plates that are insulated from each other by a capacitor dielectric.

Deep trench capacitors were traditionally formed on the frontside of a semiconductor device and connected to the transistor's source/drain regions. With the advent of backside power delivery and space saving, there is an ongoing trend to form the deep trench capacitors on the backside of the semiconductor device. With this trend, there is a need to provide a means to connect the backside deep trench capacitor to the transistor. In the present application, a semiconductor device is provided including a backside deep trench capacitor present in a deep trench device region and electrically connected to a source/drain region of a transistor and to a backside BEOL structure. In the present application, the electrical connection of the deep trench capacitor to the source/drain region of the transistor is through a combination of a backside via contact structure, a frontside power via structure and a frontside power via structure-to-source/drain contact structure. In some embodiments, the semiconductor device can also include a logic device region including at least one logic transistor that is located adjacent to the deep trench device region. These and other aspects of the present application will now be described in greater detail.

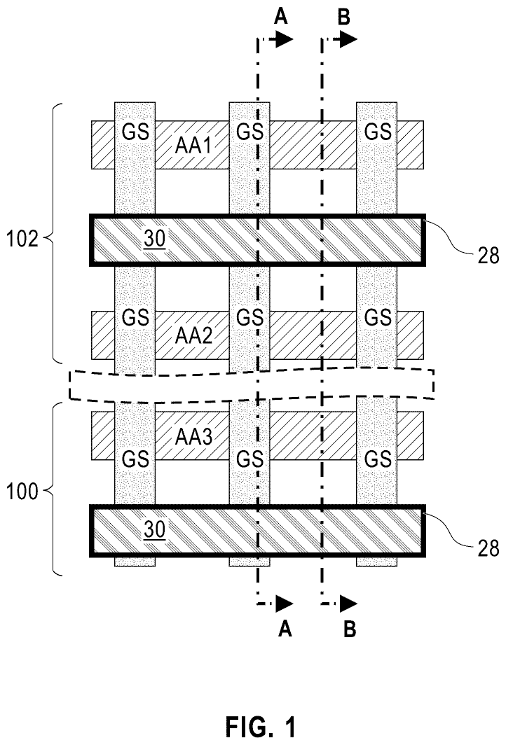

Referring first to FIG. 1, there is illustrated a device layout that can be employed in the present application. The device layout illustrated in FIG. 1 includes a logic device region 102 and a deep trench device region 100. Although the illustrated device layout includes logic device region 102, the present application works in embodiments in which the logic device region 102 is omitted or replaced with another type of device region such as, for example, a memory device region.

When present, the logic device region 102 is a region in which logic devices will be formed. The deep trench device region 100 is a region in which a backside deep trench capacitor will be formed. In FIG. 1, the logic device region 102 includes two active device areas, notably, first active device area AA1 and second active device area AA2. AA1 and AA2 are separated by a non-active device area. A non-active device area is an area in which active semiconductor devices are not formed. The logic device region 102 also includes at least one gate structure GS, three of which are shown by way of one example in FIG. 1. Each gate structure in the logic device region 102 runs parallel to each other and perpendicular to AA1 and AA2 as shown in FIG. 1. Each gate structure passes through an active device area that is present in the logic device region 102.

The deep trench device region 100 is a region in which a backside deep trench capacitor will be formed. The backside deep capacitor will be electrically connected to a source/drain region of a transistor present in the deep trench device region 100. In FIG. 1, the deep trench device region 100 includes a single active device region, i.e., third active device area AA3. Although a single active device region is shown in the deep trench device region 100, a plurality of spaced apart active device regions can be present in deep trench device region 100. A non-active device region is located adjacent to AA3 as shown in FIG. 1. The deep trench device region 100 is spaced apart from the logic device region 102 as shown by the doted region illustrated in FIG. 1. The deep trench device region 100 also includes at least one gate structure GS, three of which are shown by way of one example in FIG. 1. Each gate structure in the deep trench device region 100 runs parallel to each other and perpendicular to AA3 as shown in FIG. 1. Note that each gate structure present in the deep trench device region 100 coincides with a gate structure present in the logic device region 102.

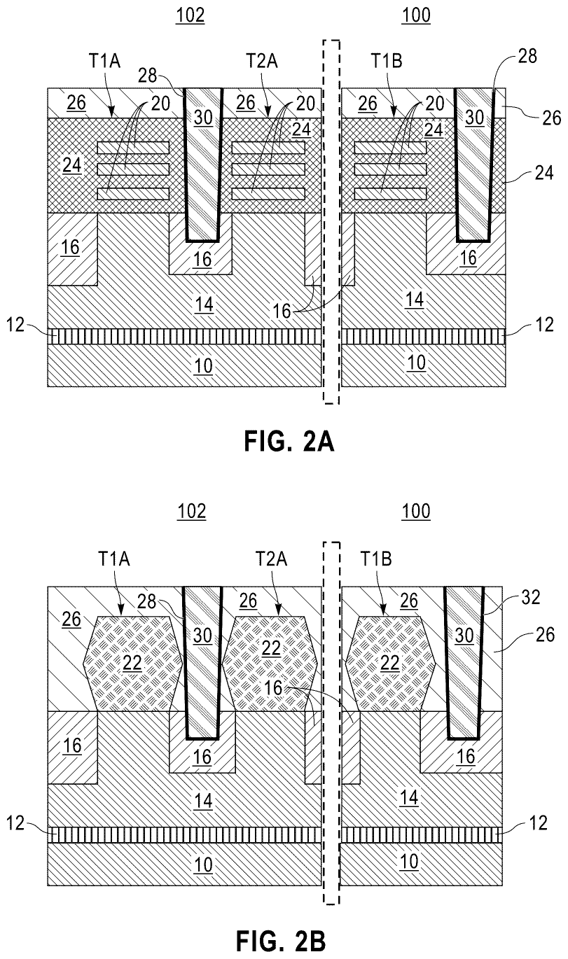

The gate structures in the deep trench device region 100 and the logic device region 102 are cut as shown in FIG. 1 by a gate cut structure that includes a gate cut dielectric pillar 30 that is surrounded by a gate cut liner 28. The gate cut structure including the gate cut liner 28 and the gate cut dielectric pillar 30 will be described in greater detail with respect to FIGS. 2A-2B. Note that each gate cut structure illustrated in FIG. 1 is oriented parallel to each of AA1, AA2 and AA3, and perpendicular to each gate structure.

FIG. 1 further includes cut A-A used for illustrating the exemplary first structure and the exemplary second structure shown in FIGS. 2A, 4A and 6A-14A, and cut B-B used for illustrating the exemplary second structure and the exemplary second structure shown in FIGS. 2B, 4B and 6B-14B. Cut A-A and cut B-B run in a same direction as shown in FIG. 1 and both cuts are present in the deep trench device region 100 and the logic device region 102. Cut A-A runs through a gate structure that is present in both the deep trench device region 100 and the logic device region 102, while cut B-B is present in a source/drain region that is located adjacent to the gate structure highlighted by cut A-A.

Referring now to FIGS. 2A-2B, there are illustrated an exemplary first structure in the logic device region 102 and an exemplary second structure in the deep trench device region 100 and through cut A-A and cut B-B, respectively, that can be employed in accordance with an embodiment of the present application. At this point of the present application, the exemplary first structure in the logic device region 102 and the exemplary second structure in the deep trench device region 100 are structurally identical. Notably, each exemplary structure, i.e., the exemplary first structure in the logic device region 102 and the exemplary second structure in the deep trench device region 100 includes a substrate (including at least a semiconductor device layer 14), a shallow trench isolation structure 16 present in an upper portion of the substrate (i.e., in an upper portion of the semiconductor device layer 14), a vertical stack of semiconductor channel material nanosheets 20 (i.e., vertical nanosheet stack), a gate structure 24 contacting each semiconductor channel material nanosheet 20 of the vertical stack of semiconductor channel material nanosheets 20, source/drain regions 22 and a first frontside interlayer dielectric (ILD) layer 26. The first frontside ILD layer 26 is located atop the gate structure 24 and embeds the source/drain regions 22.

In the present application, each combination of a vertical stack of semiconductor channel material nanosheets 20, gate structure 24 and source/drain regions 22 forms a transistor. Each transistor includes a pair of source/drain regions 22. In the illustrated embodiment, a first logic transistor T1A and a second logic transistor T2A (in some embodiments T2A is optional) are present in the logic device region 102, and T1A and T2A are separated by a gate cut structure including the gate cut liner 28 and the gate cut dielectric pillar 30. Notably, the gate cut structure cuts the gate structure 24 between T1A and T2A as shown in FIG. 1 and is present between the source/drain regions 22 of T1A and T2A. In the illustrated embodiment, at least a first deep trench device transistor T1B is present in the deep trench device region 100. A gate cut structure including the gate cut liner 28 and the gate cut dielectric pillar 30 can be adjacent to T1B as shown in FIG. 2A and is located adjacent to the source/drain regions 22 of T1B. Each gate cut structure lands on a sub-surface of one of the shallow trench isolation structures 16 and is present in the first frontside ILD layer 26. The term “sub-surface” is used to define a surface of a material/structure that is located between a topmost surface and a bottommost surface of that material/structure.

The various elements/components mentioned above for the exemplary first structure in the logic device region 102 and an exemplary second structure in the deep trench device region 100 will now be described in greater detail.

As mentioned above, the substrate includes at least semiconductor device layer 14. In addition to the semiconductor device layer 14, the substrate can also include a semiconductor base layer 10 and/or an etch stop layer 12. Embodiments are contemplated in which the semiconductor base layer 10 and/or the etch stop layer 12 are omitted and the substrate includes only the semiconductor device layer 14. The semiconductor base layer 10 is composed of a first semiconductor material, and the semiconductor device layer 14 is composed of a second semiconductor material. As used throughout the present application, the term “semiconductor material” denotes a material that has semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material that provides the semiconductor device layer 14 can be compositionally the same as, or compositionally different from, the first semiconductor material that provides the semiconductor base layer 10. In some embodiments of the present application, the etch stop layer 12 can be composed of a dielectric material such as, for example, silicon dioxide and/or boron nitride. In other embodiments of the present application, the etch stop layer 12 is composed of a third semiconductor material that is compositionally different from the first semiconductor material that provides the semiconductor base layer 10 and the second semiconductor material that provides the semiconductor device layer 14. In one example, the semiconductor base layer 10 is composed of silicon, the etch stop layer 12 is composed of silicon dioxide, and the semiconductor device layer 14 is composed of silicon. In another example, the semiconductor base layer 10 is composed of silicon, the etch stop layer 12 is composed of silicon germanium, and the semiconductor device layer 14 is composed of silicon.

Each shallow trench isolation structure 16 is located in an upper portion of the substrate and is located between the various active device areas in the deep trench device region 100 and the logic device region 102. Notably, each shallow trench isolation structure 16 is present in the semiconductor device layer 14 of the substrate, as illustrated in FIGS. 2A-2B. Each shallow trench isolation structure 16 can include a trench dielectric liner and a trench dielectric material. The trench dielectric liner includes a trench dielectric liner material such as, for example, silicon nitride. The trench dielectric material is composed of any trench dielectric such as, for example, silicon dioxide. The trench dielectric liner is present along a sidewall and a bottom wall of the trench dielectric material. In some embodiments, each shallow trench isolation structure 16 can have a topmost surface that is substantially coplanar with a topmost surface of the substrate (e.g., the semiconductor device layer 14). In other embodiments, each shallow trench isolation structure 16 can have a topmost surface that is vertically offset (i.e., higher or lower) than a topmost surface of the substrate (e.g., the semiconductor device layer 14).

Each semiconductor channel material nanosheet 20 is composed of a fourth semiconductor material. The fourth semiconductor material can be compositionally the same as, or compositionally different from, the second semiconductor material that provides the semiconductor device layer 14. In some embodiments, the fourth semiconductor material that provides each semiconductor channel material nanosheet 20 provides high channel mobility for NFET devices. In other embodiments, the fourth semiconductor material that provides each semiconductor channel material nanosheet 20 provides high channel mobility for PFET devices. In one example, each semiconductor channel material nanosheet 20 is composed of silicon. The number of semiconductor channel material nanosheets 20 present in each vertical stack of semiconductor channel material nanosheets 20 can vary and it not limited to three as exemplified in FIG. 2A.

Each source/drain region 22 is located on opposing sides of a given vertical stack of semiconductor channel material nanosheets 20. Each source/drain region 22 extends outward from a sidewall of the semiconductor channel material nanosheets 20 of a given vertical stack of semiconductor channel material nanosheets 20. Each source/drain region 22 is composed of a fifth semiconductor material and a dopant. As used herein, a “source/drain” region can be a source region or a drain region depending on subsequent wiring and application of voltages during operation of the transistor. The fifth semiconductor material that provides the source/drain regions 22 can be compositionally the same as, or compositionally different from, the fourth semiconductor material that provides each semiconductor channel material nanosheet 20. The dopant that is present in the source/drain regions 22 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each source/drain region 22 can have a dopant concentration of from 4×10²⁰ atoms/cm³ to 3×10²¹ atoms/cm³. As is shown, each source/drain region 22 contacts a surface of the semiconductor device layer 14 of the substrate.

Each gate structure 24 includes a gate dielectric material and a gate electrode, both of which are not separately shown, but intended to be within the region defined by the gate structure. As is known to those skilled in the art, a gate dielectric material directly contacts a physically exposed surface(s) of the semiconductor channel region, and a gate electrode is formed on the gate dielectric material. The gate dielectric material has a dielectric constant of 4.0 or greater. All dielectric constants mentioned herein are measured in a vacuum, unless stated to the contrary. Illustrative examples of gate dielectric materials include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The gate dielectric material can further include dopants such as lanthanum (La), aluminum (Al) and/or magnesium (Mg). The gate electrode can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to, aluminum (Al), tungsten (W), or cobalt (Co).

The first frontside ILD layer 26 is composed of ILD material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0.

The gate cut liner 28 of each gate cut structure is composed of a first dielectric material, while the gate cut dielectric pillar 30 is composed of a second dielectric material that is compositionally different as compared to the first dielectric material such that the gate cut liner 28 and the gate cut dielectric pillar 30 of each gate cut structure have different etch rates. The first dielectric material that provides the gate cut liner 28 includes, for example, SiO₂, SiN, SiBCN, SiOCN or SiOC. The second dielectric material that provides the gate cut dielectric pillar 30 includes, for example, SiN, SiOCN, SiBCN, or SiO₂. In one example, the first dielectric material that provides the gate cut liner 28 is SiO₂, while the second dielectric material that provides the gate cut dielectric pillar 30 is SiN. As is shown in FIGS. 2A and 2B, the gate cut liner 28 is present on a sidewall and a bottom surface of the gate cut dielectric pillar 30.

It should be noted that the exemplary first structure and the exemplary second structure shown in FIGS. 2A-2B would also include a gate spacer located along a sidewall of the gate structure 24 and inner spacers located beneath and at each of the ends of the semiconductor channel material nanosheets 20. The gate spacer and the inner spacers are not shown in cuts A-A and B-B used in illustrating FIGS. 2A-2B, respectively.

The exemplary first structure and the exemplary second structure shown in FIGS. 2A-2B can be formed utilizing any well-known nanosheet transistor device fabrication process in which a gate cut process is employed. The nanosheet transistor device fabrication process typically includes the use of a sacrificial gate structure which is used in defining a nanosheet stack of alternating sacrificial semiconductor nanosheets and semiconductor channel material nanosheets. After defining the nanosheet stack, the sacrificial gate structure is removed to reveal the underlying nanosheet stack and thereafter each sacrificial semiconductor material nanosheet of the nanosheet stack is removed and thereafter a gate structure is formed wrapping around each of the suspended semiconductor channel material nanosheets of the nanosheet stack. A gate cut process is performed after forming the gate structure.

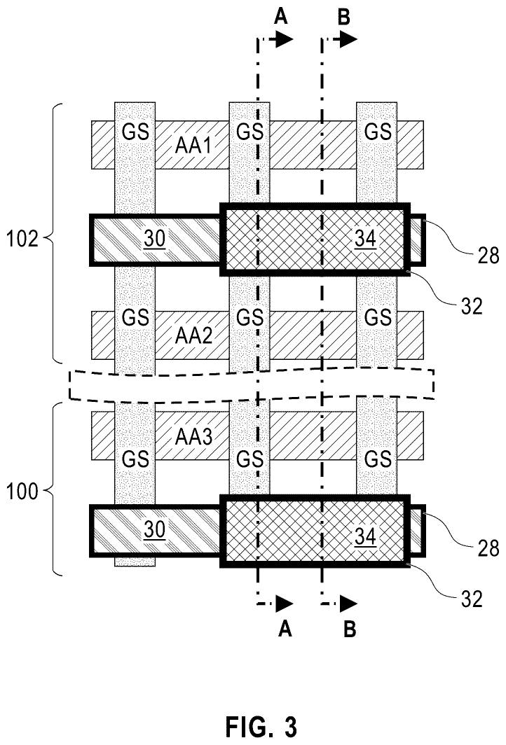

Referring now to FIG. 3, there is illustrated a top down view of a device layout as shown in FIG. 1 and including a frontside power via structure. The frontside power via structure includes a power via liner 32 and a power via pillar 34. As is shown in FIG. 3, the power via liner 32 surrounds the power via pillar 34. As is further shown in FIG. 3, the frontside power via structure is formed in contact with a remaining portion of the gate cut structure.

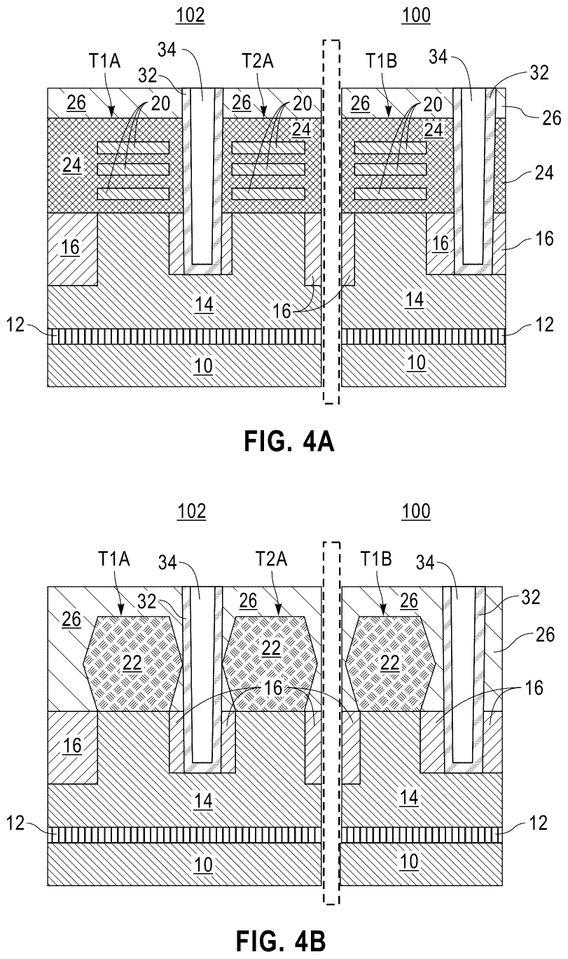

Referring now to FIGS. 4A-4B, there are illustrated the exemplary first structure and the exemplary second structure of FIGS. 2A-2B, respectively, after forming a frontside power via structure including the power via liner 32 and the power via pillar 34 mentioned above in respect to FIG. 3 in each of the deep trench device region 100 and the logic device region 102. The forming of the frontside power via structures includes a power via patterning process in which a power via mask is formed on a surface of the first frontside ILD layer 26 by deposition and lithography. The power via mask has openings present therein which physically expose a portion of each gate cut structure in the deep trench device region 100 and the logic device region 102. A first etching process can be used to remove the physically exposed gate cut dielectric pillar 30, and a second etching process can be used to remove the gate cut liner 28 that is not covered by the power via mask in each of the deep trench device region 100 and the logic device region 102.

A third etching process can then be performed to remove the trench dielectric material of the shallow trench isolation structure 16 that is not protected by the power via mask in each of the deep trench device region 100 and the logic device region 102. The removal of the trench dielectric material provides a power via opening (not specifically shown) in each of the deep trench device region 100 and the logic device region 102 that reveals a sub-surface of the semiconductor device layer 14.

After forming the power via openings, the power via mask is removed and a metallization process is used in forming the frontside power via structure including the power via liner 32 and the power via pillar 34 in in each of the deep trench device region 100 and the logic device region 102. The metallization process includes first forming a power via liner material layer (not shown) in each of the power via openings and on top of the first frontside ILD layer 26. The metallization process continues by forming a contact conductor material on the power via liner material layer. A planarization process such as, for example, chemical mechanical polishing (CMP), can then be employed to remove the contact conductor material and the power via liner material layer that is formed outside of the power via openings and on top of the first frontside ILD layer 26. The power via liner material layer that remains in the each of the power via openings provides the power via liner 32 and the contact conductor material that remains in each of the power via openings process the power via pillar 34. As shown, the power via liner 32 is present on a sidewall and a bottom surface of the power via pillar 34. It is noted that each frontside power via structure passes through one of the shallow trench isolation structures 16 and lands on a sub-surface of the semiconductor device layer 14.

In some embodiments, the power via liner material layer that provides the power via liner 32 can be an adhesion metal material such as, for example, Ti, Ta, TiN, TiN or any combination thereof. In such embodiments, the adhesion metal material can be formed by a deposition process such, as for example, chemical vapor deposition (CVD), plasma enhanced chemical vapor deposition (PECVD), atomic layer deposition (ALD) or physical vapor deposition (PVD). In some embodiments, the power via liner material layer that provides the power via liner 32 can be composed of a silicide such as, for example, as TiSi, NiSi, NiPtSi or any combination thereof. In such embodiments, the silicide is formed utilizing a silicidation process that is well known to those skilled in the art. In yet other embodiments, the power via liner material layer that provides the power via liner 32 includes a combination of an adhesion metal materiel and a silicide. The contact conductor material that provides the power via pillar 34 includes for example, W, Cu, Al, Co, Ru, Mo, Os, Ir, Rh, or an alloy thereof. The contact conductor material can be formed by any suitable deposition method such as, for example, CVD, ALD, PVD or plating.

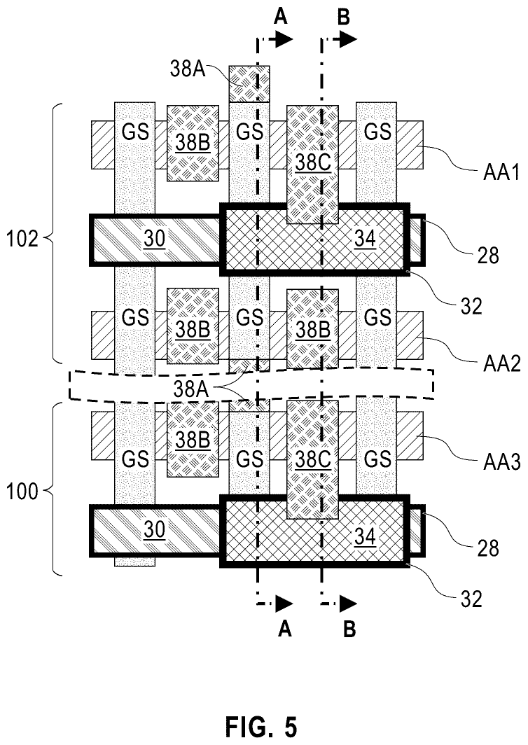

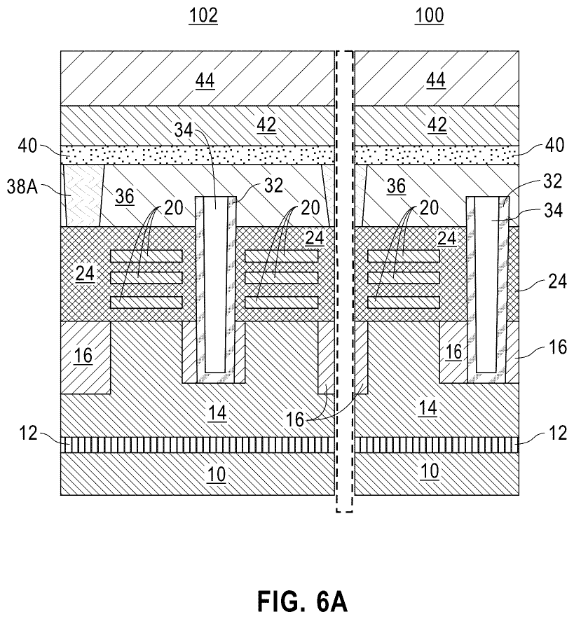

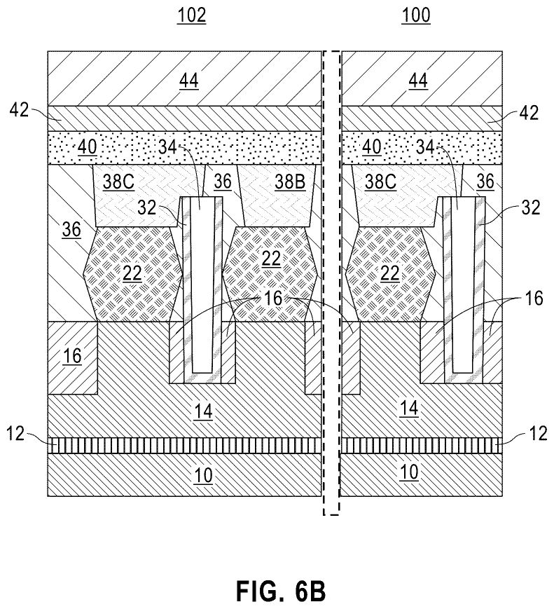

Referring now to FIG. 5, there is illustrated a top down view of a device layout as shown in FIG. 3 and including frontside contact structures. The frontside contact structures include frontside gate contact structures 38A, frontside source/drain contact structures 38B, and frontside power via structure-to-source/drain contact structures 38C. These frontside contact structures will be described in greater detail in reference to FIGS. 6A-6B.

Referring now to FIGS. 6A-6B, there are illustrated the exemplary first structure and the exemplary second structure of FIGS. 4A-4B, respectively, after forming a middle-of-the-line (MOL) level including frontside contact structures (including frontside gate contact structures 38A, frontside source/drain contact structures 38B (one of which is illustrated in FIG. 6B), and frontside power via structure-to-source/drain contact structures 38C), a frontside BEOL structure 40, and a carrier wafer 44. The MOL level is formed by first forming second frontside ILD layer (not specifically labeled in FIGS. 6A-6B) on the exemplary semiconductor structure shown in FIGS. 4A-4B. In some areas, the second frontside ILD layer contacts the first frontside ILD layer 26. Collectively, the first frontside ILD layer 26 and the second frontside ILD layer provide a multi-layered MOL structure 36. The second frontside ILD layer can be composed of a compositionally same, or compositionally different, ILD material than the first frontside ILD layer 26. When the first frontside ILD layer 26 and the second frontside ILD layer are composed of a compositionally same ILD material, no material interface is present between the two ILD layers (such an embodiment in illustrated in FIGS. 6A-6B). When the first frontside ILD layer 26 and the second frontside ILD layer are composed of compositionally different ILD materials, a material interface (not shown) is present between the two ILD layers. The second frontside ILD layer can be formed by a deposition process, followed by a planarization process.

The MOL level formation continues by forming various frontside contact structures including frontside gate contact structures 38A, frontside source/drain contact structures 38B, and frontside power via structure-to-source/drain contact structures 38C. In the present application, each frontside gate contact structure 38A contacts the contact electrode of one of the gate structures 24 (See, for example, FIG. 5 and FIG. 6A), each frontside source/drain contact structures 38B contacts one of the source/drain regions 22 of a specific transistor (see, for example, FIG. 5 and FIG. 6B), and each frontside power via structure-to-source/drain contact structures 38C has a first surface that contacts the frontside power via structure, and a second surface that contacts another of the source/drain regions 22 of the given transistor (See, for example, FIG. 5 and FIG. 6B). Each of the frontside contact structures is composed of at least a contact conductor material as exemplified above. Each of frontside contact structures can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as exemplified above. Each of the frontside contact structures can be formed by a metallization process which includes forming (by lithography and etching) frontside contact openings in the MOL multi-layered structure 36, and then filling each frontside contact opening with at least a contact conductor material as exemplified above. The filling of each frontside contact opening can include a deposition process (such as, for example, CVD, PECVD, ALD or sputtering), followed by a planarization process.

The frontside BEOL structure 40 is formed on top of the MOL level. The frontside BEOL structure 40 is composed of an interconnect dielectric region having frontside metal wiring embedded therein; the frontside metal wiring present in the frontside BEOL structure 40 is typically signal wires. The interconnect dielectric region includes one or more interconnect dielectric material layers. The interconnect dielectric material layers can be composed of at least one of the ILD materials mentioned above. The frontside metal wiring can be in the form of metal lines, metal vias, a metal via/metal line combination or any combinations thereof. The frontside metal wiring is composed of an electrically conductive metal or an electrically conductive metal alloy. Exemplary electrically conductive metals include, but are not limited to, Cu, W, Al, Co, or Ru. An exemplary electrically conductive metal alloy is a Cu—Al alloy. The frontside BEOL structure 40 can be formed utilizing any well-known BEOL process including a damascene process or a subtractive metal etch process. It is noted that the frontside BEOL structure 40 is electrically connected to each of the transistors through the frontside contact structures described above.

After forming the frontside BEOL structure 40, carrier wafer 44 is formed on the frontside BEOL structure 40. Carrier wafer 44 can include a semiconductor material as exemplified above. Carrier wafer 44 is bonded to the frontside BEOL structure 40 by bonding dielectric layer 42. Illustrative examples of dielectric materials that are used as the bonding dielectric layer 42 include, but are not limited to, tetraethyl orthosilicate (TEOS), SiO₂ silicon carbon nitride (SiCN) and/or carbon-doped silicon oxide (SiCOH). The bonding includes any bonding process that is well known to those skilled in the art. This concludes the frontside processing of the exemplary first and second structures, backside processing will now be performed.

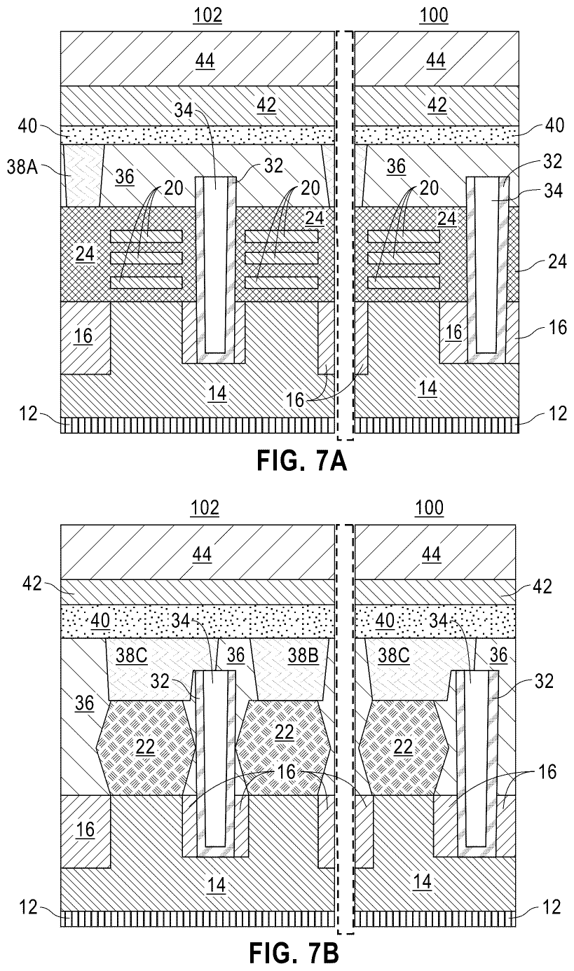

Referring now to FIGS. 7A-7B, there are illustrated the exemplary first structure and the exemplary second structure of FIGS. 6A-6B, respectively, after wafer flipping, and removal of the semiconductor base substrate layer 10 of the substrate. In the present application, backside processing begins by flipping the exemplary first structure and the exemplary second structure of FIGS. 6A-6B 180° to physically expose a backside of the structure. For clarity, the flipping step is not shown in the drawings. Flipping can be performed by hand or by utilizing a mechanical means such as, for example, a robot arm. After flipping, and in the illustrated embodiment, the semiconductor base layer 10 is physically exposed and the physically exposed semiconductor base layer 10 is removed utilizing a material removal process that is selective in removing the semiconductor material that provides the semiconductor base layer 10. The removal of the semiconductor base layer 10 reveals the etch stop layer 12 of the substrate. The removal of the semiconductor base layer 10 can be omitted when no semiconductor base layer 10 is present in the substrate.

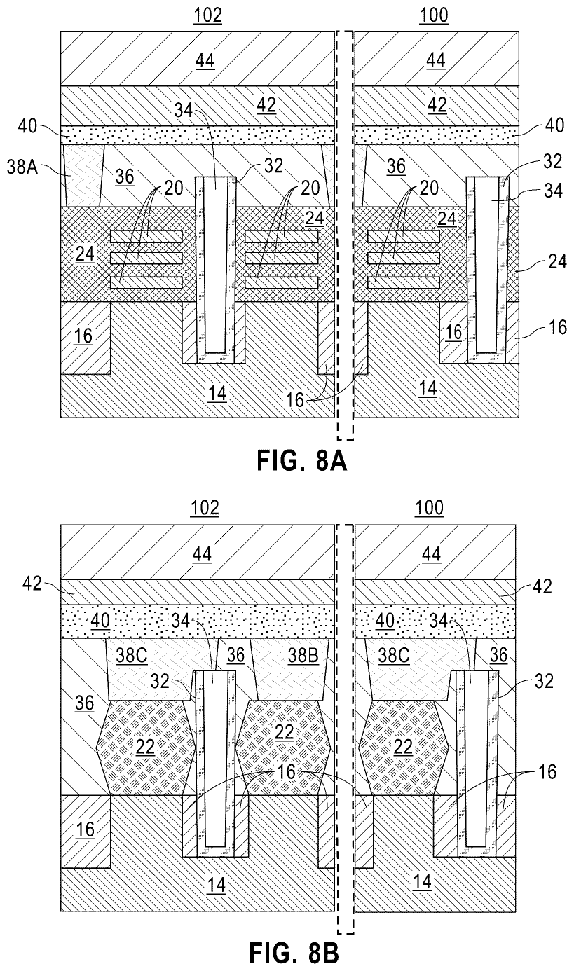

Referring now to FIGS. 8A-8B, there are illustrated the exemplary first structure and the exemplary second structure of FIGS. 7A-7B, respectively, after removing the etch stop layer 12 of the substrate. The etch stop layer 12 can be removed utilizing a material removal process that is selective in removing the material that provides the etch stop layer 12. The removal of the etch stop layer 12 physically exposes the semiconductor device layer 14. It is noted that the removal of the etch stop layer 12 can be omitted when such a layer is not present. In some embodiments and following the removal of the etch stop layer 12, the semiconductor device layer 14 can be thinned utilizing an etching process or a planarization process.

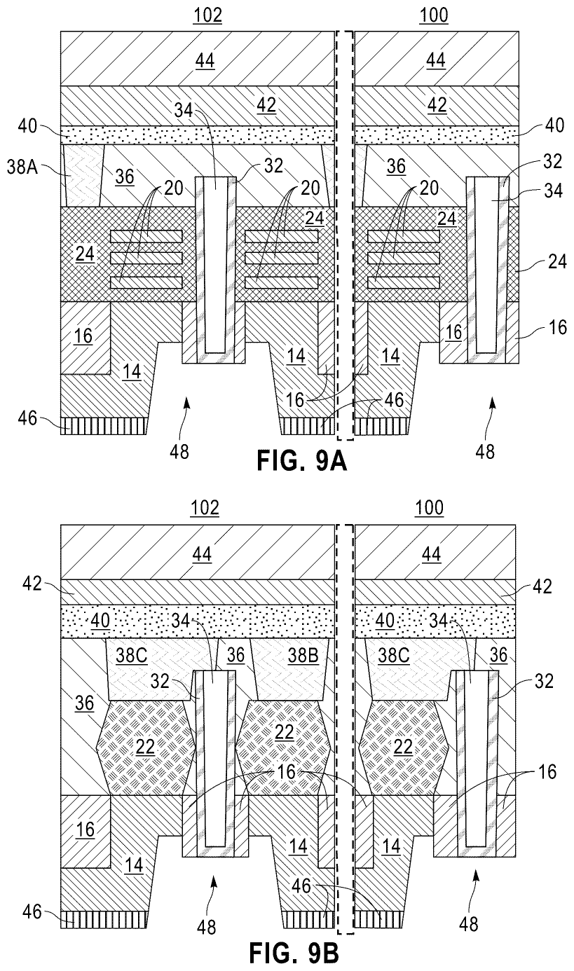

Referring now to FIGS. 9A-9B, there are illustrated the exemplary first structure and the exemplary second structure of FIGS. 8A-8B, respectively, after forming backside contact via openings 48 in the semiconductor device layer 14. The backside contact via openings 48 are formed by first depositing (e.g. CVD, PECVD, ALD, PVD, etc.) a hard mask layer 46 on a physically exposed surface of the semiconductor device layer 14. The hard mask layer 46 is composed of one or more hard mask materials including, for example, SiO₂, SiN or silicon oxynitride. A lithographic patterning process is then performed to provide openings in the hard mask layer 46. These openings that are formed in the hard mask layer 46 coincide with the area in which the backside contact via openings 48 will be subsequently formed. The lithographic patterning includes the use of a patterned photoresist which can be removed after forming the openings in the hard mask layer 46. An etch is then performed that is selective in removing the second semiconductor material that provides the semiconductor device layer 14. In the present application, each backside contact via openings 48 has a critical dimension (i.e., width) that is greater than a critical dimension (i.e., width) of the frontside power via structure such that the backside contact via openings 48 is located adjacent to a sidewall of the frontside power via structure as is illustrated in FIGS. 9A-9B. Each backside contact via openings 48 physically exposes a bottom surface of the power via liner 32, as well as surfaces (sidewall and bottom surface) of the shallow trench isolation structure 16 and surfaces of the semiconductor device layer 14.

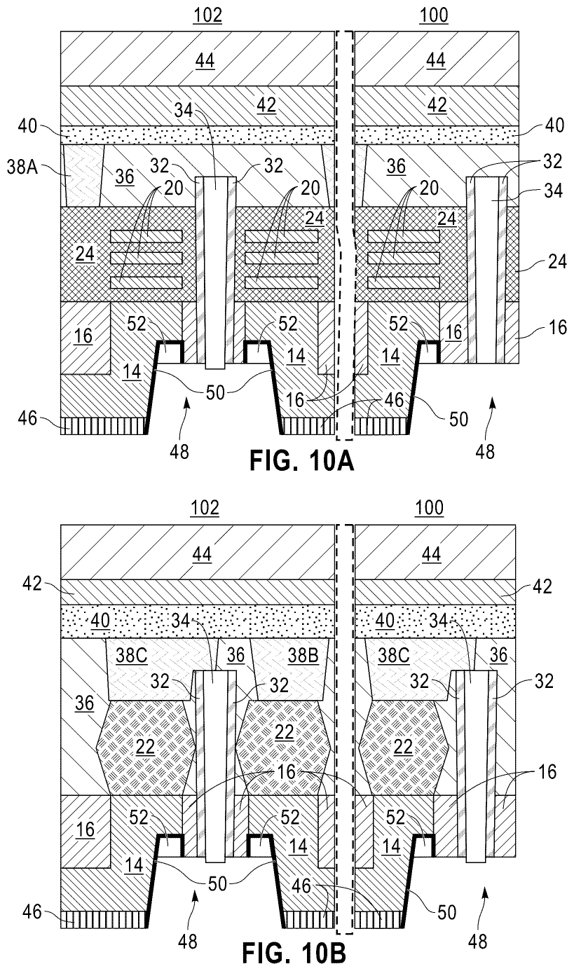

Referring now to FIGS. 10A-10B, there are illustrated the exemplary first structure and the exemplary second structure of FIGS. 9A-9B, respectively, after forming a backside via contact liner 50 and a recessed dielectric layer 52 in each backside contact via openings 48. The backside via contact liner 50 is composed of a third dielectric material (e.g., SiN, SiBCN, SiOCN or SiOC) that is compositionally different from a fourth dielectric material (e.g., SiN, SiOCN, SiBCN, or SiO₂) that is used in providing the recessed dielectric layer 52. In one example, the backside via contact liner 50 is composed of SiN, and the recessed dielectric layer 52 is composed of SiO₂. In the present application, a layer of the third dielectric material is deposited within each backside power rail opening 48 and on a surface of the hard mask layer 46. Next, the fourth dielectric material is deposited on the layer of the third dielectric material, and thereafter a planarization process and a recess etch is used in providing the backside via contact liner 50 and the recessed dielectric layer 52. In some embodiments, a bottom surface of the power via pillar 34 is then physically exposed utilizing an etch such as, for example, reactive ion etching (RIE). In other embodiments, the recess etch can be used to physically expose the power via pillar 34.

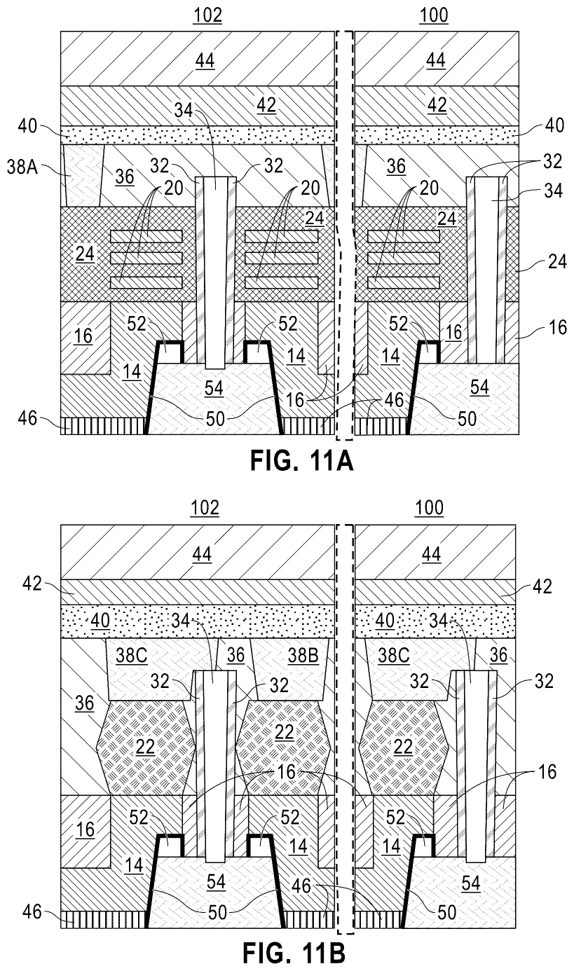

Referring now to FIGS. 11A-11B, there are illustrated the exemplary first structure and the exemplary second structure of FIGS. 10A-10B, respectively, after forming a backside contact via structure 54 in each backside power rail opening 48. The backside contact via structure 54 is composed of least a contact conductor material as exemplified above. The backside contact via structure 54 can be formed by deposition (e.g., CVD, PECVD, ALD, PVD or sputtering) of the electrically conductive power rail material, followed by planarization (e.g., CMP). As is illustrated, the backside contact via structure 54 is in direct physical contact with the power via pillar 34 of the frontside power via structure.

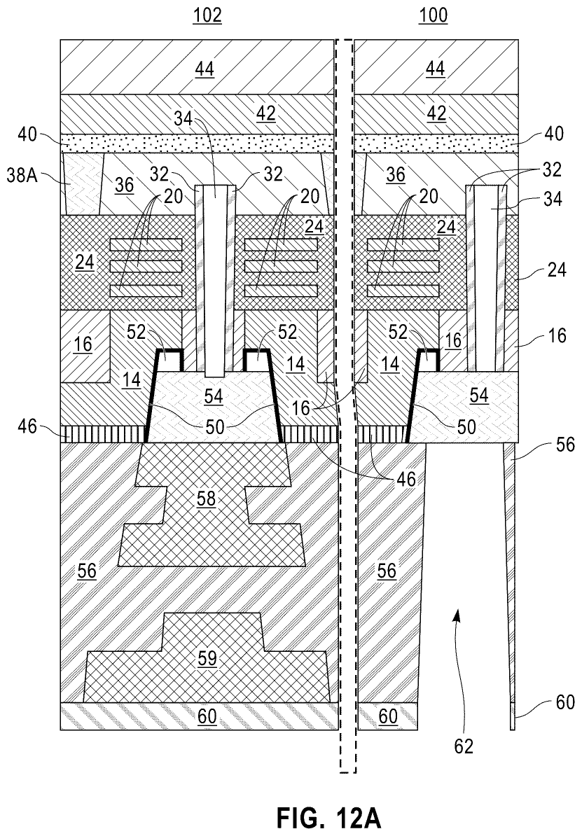

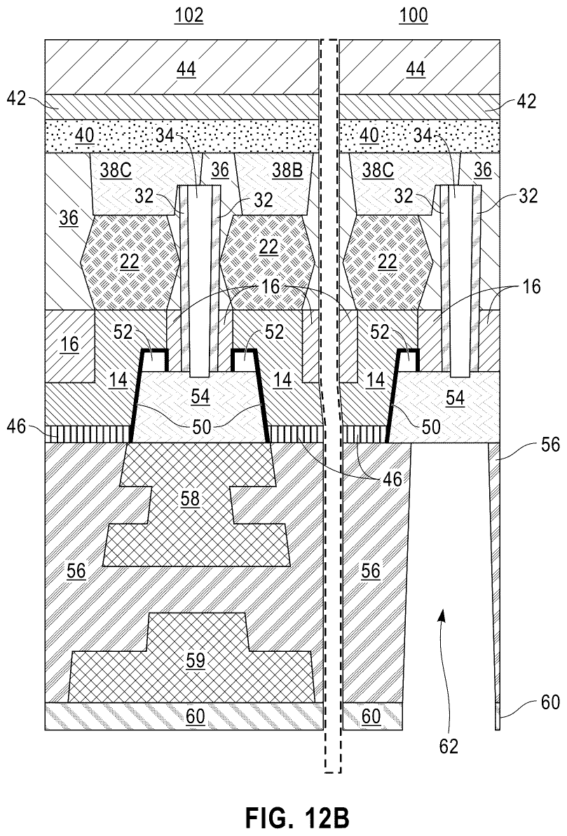

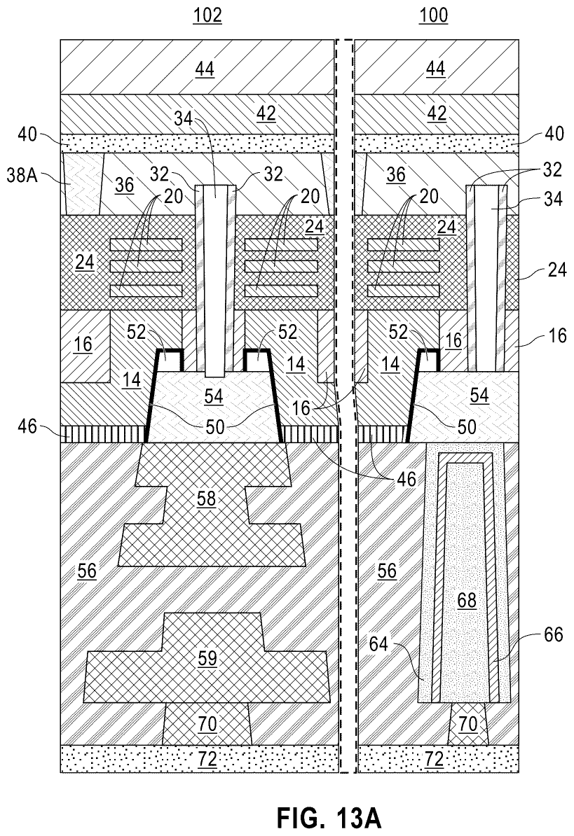

Referring now to FIGS. 12A-12B, there are illustrated the exemplary first structure and the exemplary second structure of FIGS. 11A-11B, respectively, after forming backside power rails 58, 59 in the logic device region 102 and forming a deep trench opening 62 in the deep trench device region 100. In the present application, the backside power rails 58, 59 in and the deep trench opening 62 are formed in a multi-layered backside interlayer dielectric (ILD) structure 56 that is composed of a plurality of ILD materials. The plurality of ILD materials that provide the multi-layered backside ILD structure 56 are formed utilizing a same or different deposition process (e.g., CVD, PECVD and/or spin-on coating). In the present application, the multi-layered backside ILD structure 56 is formed in both the logic device region 102 and the deep trench device region 100.

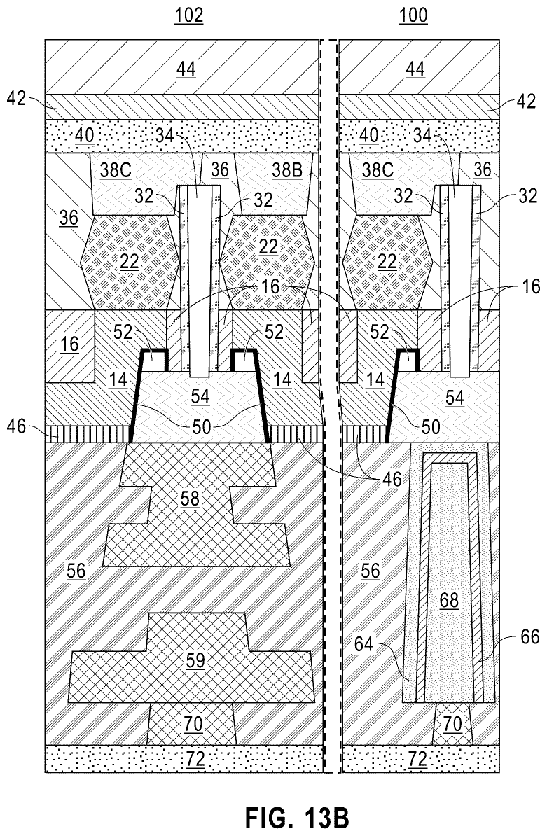

The backside power rails 58, 59 are composed of an electrically conductive power rail material including, but not limited to, W, Co, Ru, Al, Cu, Pt, Rh, or Pd. In the present application, the backside power rails 58, 59 include a combination of lines and vias stacked as shown. The backside power rails 58, 59 can be electrically connected by other additional backside power rails (not shown in FIGS. 13A and 13B). Backside power rail 58 is in electrically contact with the backside contact via structure 54 that is present in the logic device region 102. The backside power rail 58, 59 can be formed utilizing a metallization process. After forming the backside power rail 59 in the logic device region 102, a masking layer 60 is formed on a surface of the multi-layered backside ILD structure 56 that is present in both the logic device region 102 and the deep trench device region 100. The masking layer 60 can be composed of one or more masking materials. In one example, the masking layer 60 can be composed of an organic planarization material. The masking layer 60 can be formed by a deposition process such as, for example, CVD, PECVD or spin-on coating. After deposition of the masking layer 60, the masking layer 60 is opened in the deep trench device region 100 by lithography and etching. After opening the masking layer 60 in the deep trench device region 100, a deep trench opening 62 is formed utilizing a deep trench etching process. The deep trench etching process removes a physically exposed portion of the multi-layered backside ILD structure 56 in the deep trench device region 100. The deep trench etching process stops on a surface of the backside contact via structure 54 that is present in the deep trench device region 100. The masking layer 60 is removed after forming the deep trench opening 62 utilizing a material removal process that is selective in removing the masking material(s) that provide the masking layer 60.

Referring now to FIGS. 13A-13B, there are illustrated the exemplary first structure and the exemplary second structure of FIGS. 12A-12B, respectively, after forming a backside deep trench capacitor in the deep trench opening 62, last level backside power vias 70 and a backside BEOL structure 72. The backside deep trench capacitor includes a first electrode plate 64, and a second electrode plate 68 that spaced apart by a capacitor dielectric 66. The first electrode plate 64 and the second electrode plate 68 can be singled layered structures or muti-layered structures. The first electrode plate 64 and the second electrode plate 68 are composed of a conductive metal-containing material. In some embodiments, the first electrode plate 64 and the second electrode plate 68 are composed of a compositionally same conductive metal-containing material. In other embodiments, the first electrode plate 64 and the second electrode plate 68 are composed of a compositionally different conductive metal-containing materials.

In the present application, the term “conductive metal-containing material” denotes a pure metal, a metal carbide compound or a metal nitride compound. Illustrative conductive metal-containing materials that can be used in providing the first electrode plate 64 and the second electrode plate 68 include, but are not limited to, titanium nitride and/or tantalum nitride. The capacitor dielectric 66 is composed one of the high k gate dielectric materials mentioned above for the gate dielectric material of the gate structure 24. The backside deep trench capacitor can be formed by deposition of a layer of first conductive metal-containing material inside and outside of the deep trench opening 62, followed by the deposition of a layer of capacitor dielectric material on the layer of first conductive metal-containing material, followed by the deposition of a layer of the second conductive metal-containing material on the layer of capacitor dielectric material. A planarization process is then used to remove the various as deposited layers that are formed outside of the deep trench opening 62. As is illustrated, the first electrode plate 64 of the backside deep trench capacitor is in direct physical contact with one of the backside contact via structures 54.

Next, an additional backside ILD material is formed by a deposition process to provide a last backside ILD layer (not specifically labeled) of the multi-layered backside ILD structure 56. Last level backside power vias 70 are then formed in this last backside ILD layer of the multi-layered backside ILD structure 56 utilizing a metallization process. The last level backside power vias 70 are composed of an electrically conductive power rail material as exemplified above. In the logic device region 102, the last level backside power via 70 is electrically connected to the backside power rail 59. In the deep trench device region 100, the last level backside power via 70 is in direct physical contact with the second electrode plate 68 of the backside deep trench capacitor.

The backside BEOL structure 72 (which can delivery power from the backside of the device) is composed of an interconnect dielectric region having backside metal wiring embedded therein. The interconnect dielectric region includes one or more interconnect dielectric material layers. The interconnect dielectric material layers can be composed of one of the ILD materials mentioned above. The backside metal wiring which can be in the form of metal lines, metal vias, a metal via/metal line combination or any combinations thereof is composed of an electrically conductive metal or an electrically conductive metal alloy, as both defined above. The backside BEOL structure 72 can be formed utilizing any well-known BEOL process including a damascene process or a subtractive metal etch process. The backside BEOL structure 72 is electrically connected to the backside power rail 59 by the last level backside power via 70 that is present in logic device region 102. The backside BEOL structure 72 is also electrically connected to the backside deep trench capacitor by the last level backside power via 70 that is present in deep trench device region 100.

Referring to the deep trench device region 100 shown in FIGS. 13A-13B, there is illustrated a semiconductor device in accordance with an embodiment of the present application. The illustrated semiconductor device in the deep trench device region 100 shown in FIGS. 13A-13B includes a deep trench device transistor (e.g., T1B) including gate structure 24 and a pair of source/drain regions (e.g., source/drain regions 22), backside deep trench capacitor (including the first electrode plate 64, capacitor dielectric 66, and second electrode plate 68) is located beneath the deep trench device transistor (e.g., T1B), and backside BEOL structure 72 is located beneath the backside deep trench capacitor. In the illustrated embodiment and in the deep trench device region 100 shown in FIGS. 13A-13B, the backside deep trench capacitor (including the first electrode plate 64, capacitor dielectric 66, and second electrode plate 68) is electrically connected to a first source/drain region (e.g., source/drain region 22 in the deep trench device region 100 shown in FIG. 13A) of the pair of source/drain regions by a combination of backside via contact structure 54, frontside power via structure (including power via liner 32 and power via pillar 34) and frontside power via structure-to-source/drain contact structure 38C, and the backside deep trench capacitor (including the first electrode plate 64, capacitor dielectric 66, and second electrode plate 68) is further electrically connected to the backside BEOL structure 72 by a last level backside power via 70.

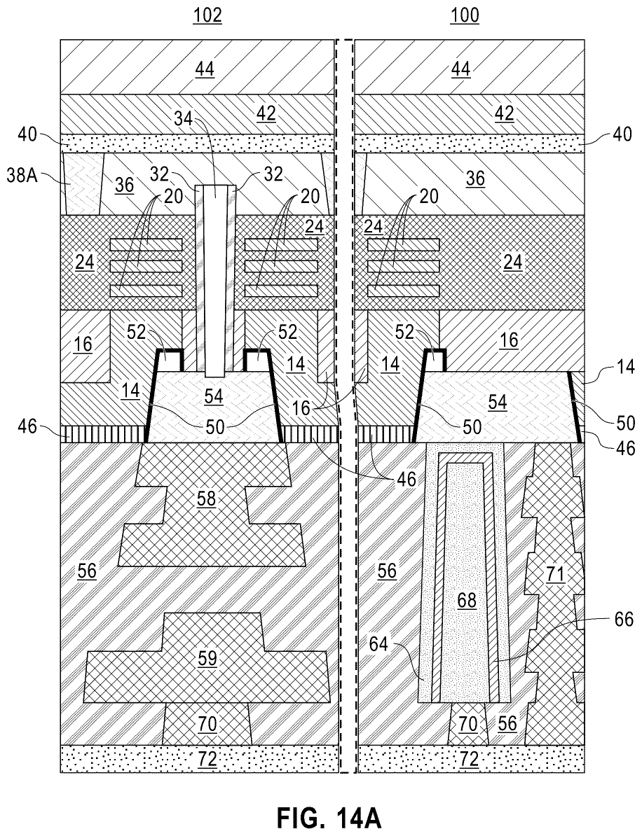

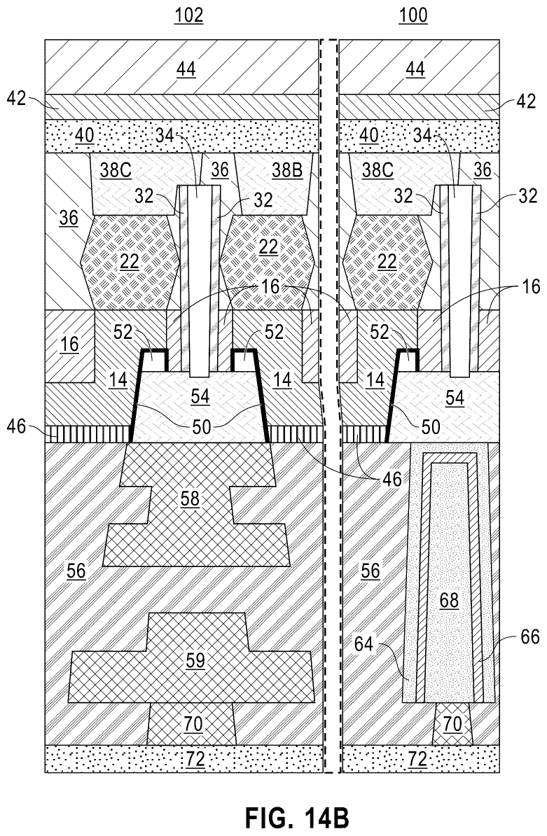

Referring now to FIGS. 14A-14B, there are illustrated the exemplary first structure and the exemplary second structure through cut A-A and cut B-B, respectively, in accordance with an alternative embodiment of the present application. Note that the exemplary first structure shown in FIGS. 14A-14B is the same as that shown in FIGS. 13A-13B. The exemplary second structure shown in FIGS. 14A-14B differs from the exemplary second structure shown in FIGS. 13A-13B in that no frontside power via structure is present in the cut A-A. In this embodiment, the frontside power via structure is laterally adjacent to only a first source/drain region of the pair of source/drain regions 22 that is present in the deep trench device region 100. In the previous embodiment shown in FIGS. 13A and 13B, the power via is located laterally adjacent to both the gate structure 24 and the first source/drain region of the pair of source/drain regions 22 that are present in the deep trench device region 100. In the illustrated embodiment of FIGS. 14A-14B, a backside power via stack 71 is present in the multi-layered backside ILD structure 56 which electrically connects the backside BEOL structure 72 to the backside contact via structure 54 that is present in the deep trench device region 100. Notably, the backside power via stack 71 includes a first surface in direct physical contact with the backside via contact structure 54, and a second surface, opposite the first surface, which is in direct physical contact with the backside BEOL structure 72. The backside power via stack 71 is composed of a plurality of backside power vias that are stacked vertically one on top the other. Each backside power via that provides the backside power via stack 71 can be formed by a metallization process and can be composed of an electrically conductive power rail material as exemplified above.

Referring to the deep trench device region 100 shown in FIGS. 14A-14B, there is illustrated a semiconductor device in accordance with an embodiment of the present application. The illustrated semiconductor device in the deep trench device region 100 shown in FIGS. 14A-14B includes a deep trench device transistor (e.g., T1B) including gate structure 24 and a pair of source/drain regions (e.g., source/drain regions 22), backside deep trench capacitor (including the first electrode plate 64, capacitor dielectric 66, and second electrode plate 68) is located beneath the deep trench device transistor (e.g., T1B), and backside BEOL structure 72 is located beneath the backside deep trench capacitor. In the illustrated embodiment the deep trench device region 100 shown in FIGS. 14A-14B, the backside deep trench capacitor (including the first electrode plate 64, capacitor dielectric 66, and second electrode plate 68) is electrically connected to a first source/drain region (e.g., source/drain region 22 in the deep trench device region 100 shown in FIG. 14A) of the pair of source/drain regions by a combination of backside via contact structure 54, frontside power via structure (including power via liner 32 and power via pillar 34) and frontside power via structure-to-source/drain contact structure 38C, and the backside deep trench capacitor (including the first electrode plate 64, capacitor dielectric 66 and second electrode plate 68) is further electrically connected to the backside BEOL structure 72 by a last level backside power via 70. In this exemplary embodiment, the semiconductor device further includes backside power via stack 71 having a first surface in direct physical contact with the backside via contact structure 54, and a second surface, opposite the first surface, which is in direct physical contact with the backside BEOL structure 72.

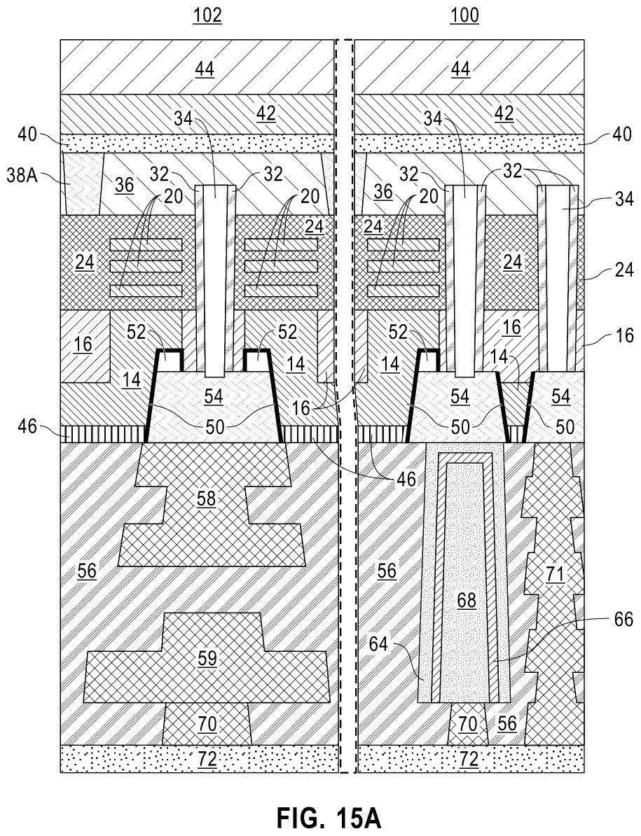

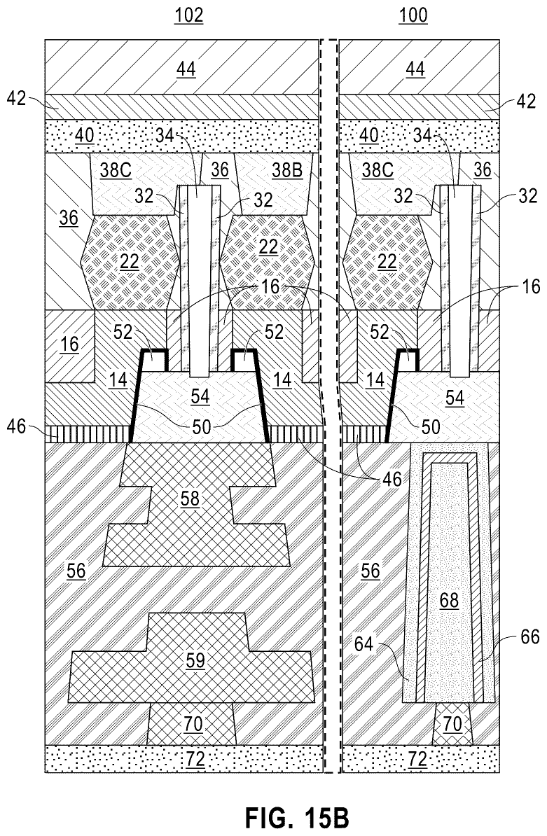

Referring now to FIGS. 15A-15B, there are illustrated the exemplary first structure and the exemplary second structure through cut A-A and cut B-B, respectively, in accordance with another alternative embodiment of the present application. Note that the exemplary first structure shown in FIGS. 14A-14B is the same as that shown in FIGS. 13A-13B. The exemplary second structure shown in FIGS. 14A-14B differs from the exemplary second structure shown in FIGS. 13A-13B in that two frontside power via structures are present in the cut A-A instead of one frontside power via structure. The two frontside power via structures are located laterally adjacent to each other as is shown in the deep trench device region 100 of FIG. 15A. Also, and in this embodiment, a backside power via stack 71 (See, FIG. 15A) is present in the multi-layered backside ILD structure 56 which electrically connects the backside BEOL structure 72 to another of the backside contact via structure 54 that is present in the deep trench device region 100. The backside power via stack 71 is composed of a plurality of backside power vias that are stacked vertically one on top the other. Each backside power via that provides the backside power via stack 71 can be formed by a metallization process and can be composed of an electrically conductive power rail material as exemplified above.

Referring to the deep trench device region 100 shown in FIGS. 15A-15B, there is illustrated a semiconductor device in accordance with another embodiment of the present application. The semiconductor device the deep trench device region 100 shown in FIGS. 15A-15B includes a deep trench device transistor (e.g., T1B) including gate structure 24 and a pair of source/drain regions (e.g., source/drain regions 22), backside deep trench capacitor (including the first electrode plate 64, capacitor dielectric 66, and second electrode plate 68) is located beneath the deep trench device transistor (e.g., T1B), and backside BEOL structure 72 is located beneath the backside deep trench capacitor. In the illustrated embodiment the deep trench device region 100 shown in FIGS. 15A-15B, the backside deep trench capacitor (including the first electrode plate 64, capacitor dielectric 66, and second electrode plate 68) is electrically connected to a first source/drain region (e.g., source/drain region 22 shown in the deep trench device region 100 shown in FIG. 15A) of the pair of source/drain regions by a combination of a first backside via contact structure (i.e., backside via contact structure 54 on the left side in the deep trench device region 100 shown in FIG. 15A), first frontside power via structure (including power via liner 32 and power via pillar 34 on the left hand side in the deep trench device region 100 shown in FIG. 15A) and frontside power via structure-to-source/drain contact structure 38C, and the backside deep trench capacitor (including the first electrode plate 64, capacitor dielectric 66 and second electrode plate 68) is further electrically connected to the backside BEOL structure 72 by a last level backside power via 70. In this embodiment, the semiconductor device further includes and a second frontside power via structure (including power via liner 32 and power via pillar 34 on the right hand side in the deep trench device region 100 shown in FIG. 15A) located laterally adjacent to the first frontside power via structure (including power via liner 32 and power via pillar 34 on the left hand side in the deep trench device region 100 shown in FIG. 15A), wherein the second frontside power via structure (including power via liner 32 and power via pillar 34 on the right hand side in the deep trench device region 100 shown in FIG. 15A) is electrically connected to the backside BEOL structure 72 by a second backside via contact structure (i.e., backside via contact structure 54 on the right hand side in the deep trench device region 100 shown in FIG. 15A) and backside power via stack 71.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a deep trench device transistor comprising a gate structure and a pair of source/drain regions;
a backside deep trench capacitor located beneath the deep trench device transistor; and
a backside back-end-of-the-line (BEOL) structure located beneath the backside deep trench capacitor, wherein the backside deep trench capacitor is electrically connected to a first source/drain region of the pair of source/drain regions by a combination of a backside via contact structure, a frontside power via structure and a frontside power via structure-to-source/drain contact structure, and the backside deep trench capacitor is further electrically connected to the backside BEOL structure by a last level backside power via.

2. The semiconductor device of claim 1, wherein the backside deep trench capacitor comprises a first electrode plate and a second electrode plate that are spaced apart by a capacitor dielectric, wherein the first electrode plate is in direct physical contact with the backside via contact structure, and the second electrode plate is in direct physical contact with the last level backside power via.

3. The semiconductor device of claim 1, wherein the backside deep trench capacitor and the last level backside power via are embedded in a multi-layered backside interlayer dielectric structure.

4. The semiconductor device of claim 1, further comprising a frontside BEOL structure located above the deep trench device transistor.

5. The semiconductor device of claim 4, wherein the frontside BEOL structure is electrically connected to a gate electrode of the gate structure of the deep trench device transistor by a frontside gate contact structure, and to the first source/drain region of the pair of source/drain regions transistor by the frontside power via structure-to-source/drain contact structure.

6. The semiconductor device of claim 1, wherein the frontside power via structure is in contact with a gate cut structure.

7. The semiconductor device of claim 1, wherein the frontside power via structure is located laterally adjacent to both the gate structure and the first source/drain region of the pair of source/drain regions.

8. The semiconductor device of claim 1, wherein the frontside power via structure is located laterally adjacent to only the first source/drain region of the pair of source/drain regions.

9. The semiconductor device of claim 8, further comprising a backside power via stack having a first surface in direct physical contact with the backside power via contact structure, and a second surface opposite the first surface, in direct physical contact with the backside BEOL structure.

10. The semiconductor device of claim 1, wherein the deep trench device transistor is located on a semiconductor device layer, and wherein the frontside power via structure passes through a shallow trench isolation structure that is present in the semiconductor device layer.

11. A semiconductor device comprising:
a deep trench device transistor comprising a gate structure and a pair of source/drain regions;
a backside deep trench capacitor located beneath the deep trench device transistor;
a backside back-end-of-the-line (BEOL) structure located beneath the backside deep trench capacitor, wherein the backside deep trench capacitor is electrically connected to a first source/drain region of the pair of source/drain regions by a combination of a first backside via contact structure, a first frontside power via structure and a frontside power via structure-to-source/drain contact structure, and the backside deep trench capacitor is further electrically connected to the backside BEOL structure by a last level backside power via; and
a second frontside power via structure located laterally adjacent to the first frontside power via structure, wherein the second frontside power via structure is electrically connected to the backside BEOL structure by a second backside via contact structure and a backside power via stack.

12. The semiconductor device of claim 11, wherein the backside deep trench capacitor comprises a first electrode plate and a second electrode plate that are spaced apart by a capacitor dielectric, wherein the first electrode plate is in direct physical contact with the first backside via contact structure, and the second electrode plate is in direct physical contact with the last level backside power via.

13. The semiconductor device of claim 11, wherein the backside deep trench capacitor, the last level backside power via, and the backside power via stack are embedded in a multi-layered backside interlayer dielectric structure.

14. The semiconductor device of claim 11, further comprising a frontside BEOL structure located above the deep trench device transistor.

15. The semiconductor device of claim 14, wherein the frontside BEOL structure is electrically connected to a gate electrode of the gate structure of the deep trench device transistor by a frontside gate contact structure, and to the first source/drain region of the pair of source/drain regions transistor by the frontside power via structure-to-source/drain contact structure.

16. The semiconductor device of claim 11, wherein at least the first frontside power via structure is in contact with a gate cut structure.

17. The semiconductor device of claim 11, wherein the first frontside power via structure is located laterally adjacent to both the gate structure and the first source/drain region of the pair of source/drain regions.

18. The semiconductor device of claim 11, wherein the deep trench device transistor is located on a semiconductor device layer, and wherein both the first frontside power via structure and the second frontside power via structure pass through a shallow trench isolation structure that is present in the semiconductor device layer.
